(19) United States
(12) Patent Application Publication
(10) Pub. No.: US 2025/0096532 A1
(43) Pub. Date: Mar. 20, 2025

(54) OPTICAL SEMICONDUCTOR DEVICE

(71) Applicant: NeoPhotonics Corporation, SAN JOSE, CA (US)

(72) Inventor: Takanori KOJIMA, Hachioji City (JP)

(21) Appl. No.: 18/591,796

(22) Filed: Feb. 29, 2024

(30) Foreign Application Priority Data
Sep. 20, 2023 (JP) 2023-151989
Dec. 6, 2023 (JP) 2023-205736

(51) Int. Cl. H01S 5/22; H01S 5/042

(52) U.S. Cl. CPC H01S 5/22; H01S 5/0427

(57) ABSTRACT

Provided is an optical semiconductor device in which electrodes have excellent connectivity and a device size is kept from increasing. In a first direction, a first bank portion, a first groove portion, a third bank portion, a third groove portion, an optical function portion, and a second bank portion are placed in this order. A distance between an upper end and a lower end of a first bank portion-side side surface in the first direction is longer than a distance between an upper end and a lower end of a third bank portion-side side surface in the first direction. The first electrode is in contact with the semiconductor layer of the first conductivity type in a bottom portion of the first groove portion, and stretches along the first bank portion-side side surface to a top surface of the first bank portion.

### CROSS-REFERENCE TO RELATED APPLICATIONS

This patent application claims priority to Japanese Patent Application number 2023-205736 filed on Dec. 6, 2023, and to Japanese Patent Application Number 2023-151989 filed on Sep. 20, 2023, the contents of which are hereby incorporated by reference into this application. The disclosure of the prior applications are considered part of and are incorporated by reference into this patent application.

### TECHNICAL FIELD

The present disclosure relates generally to an optical semiconductor device.

### BACKGROUND

An optical semiconductor device can have a semiconductor multilayer structure, in which, on a conductive or insulating semiconductor substrate, a semiconductor layer of a first conductivity type (e.g., an “n” type), a conductive or insulating optical function layer, and a semiconductor layer of a second conductivity type (e.g., a “p” type) are layered by epitaxial growth. An electrode on a first-conductivity side and an electrode on a second-conductivity side can be electrically connected to the semiconductor layer of the first conductivity type and the semiconductor layer of the second conductivity type, respectively. A voltage can be applied between the two electrodes, to thereby cause the optical function layer to perform such operation as light emission, light absorption, and light amplification. The two electrodes are generally metal films. In some cases, the electrode on the first conductivity side and the electrode on the second conductivity side are placed on the same surface.

### SUMMARY

In order to connect the electrode on the first conductivity side to the semiconductor layer of the first conductivity type, a groove is required to be formed in the semiconductor multilayer, and the electrode on the first conductivity side is required to be led out from a bottom of the groove (a surface of the semiconductor layer of the first conductivity type) to a level roughly flush with a surface on which the electrode on the second conductivity side is placed. In current uses, the electrode on the first conductivity side is led out along a side wall of the groove to a high point. In a case in which the side wall is vertical, connectivity of the electrode drops to invite issues, such as poor connection due to breaking of the electrode, and an increase in resistance. This can be solved by giving the side wall of the groove a tapered shape.

However, when the side wall of the groove is given a tapered shape, the following problems arise. One problem is an increase in cost due to an increase in size of the optical semiconductor device. For example, when a side wall of a groove portion is given a tapered shape, the electrode on the first conductivity side is placed so as to stretch in a direction away from an optical function layer side. Compared to the vertical side wall, a distance along which the electrode stretches is longer because the electrode stretches over a tapered portion, and the longer distance leads to an increase in device size. Another problem is that a distance from a place of a connection surface on which the semiconductor layer of the first conductivity type and the electrode on the first conductivity side are connected to each other to a place of connection between the semiconductor layer of the first conductivity type and the optical function layer increases. In some cases, both side walls of the groove have a tapered shape and a distance between the optical function layer and the electrode on the first conductivity side is long as a result. This invites an increase in electrical resistance, which is a disadvantage in terms of power consumption. Further, there is a concern for stability of a process in forming of the taper-shaped side walls.

Some implementations described herein include an optical semiconductor device that solves one or more of the problems described above. As an example, some implementations include an optical semiconductor device in which, in a structure that places two electrodes on a same surface, the two electrodes have excellent connectivity and a device size is prevented from increasing.

In some implementations, there is provided an optical semiconductor device that includes: a semiconductor layer of a first conductivity type; an optical function layer placed above the semiconductor layer of the first conductivity type; a semiconductor layer of a second conductivity type placed above the optical function layer; a first electrode electrically connected to the semiconductor layer of the first conductivity type; a second electrode electrically connected to the semiconductor layer of the second conductivity type; a first bank portion in which a part of the first electrode is placed; a first groove portion adjacent to the first bank portion; a second bank portion in which a part of the second electrode is placed; a third bank portion; a third groove portion adjacent to the third bank portion; and an optical function portion including the optical function layer. In a second direction that is, in plan view, perpendicular to a first direction along which the optical function portion stretches, the first bank portion, the first groove portion, the third bank portion, the third groove portion, the optical function portion, and the second bank portion are placed in the stated order. The second electrode is in contact with the semiconductor layer of the second conductivity type in the optical function portion. A first bank portion-side side surface, which is a side surface of the first groove portion on the first bank portion side, has a stepped shape including a terrace portion. A distance between an upper end and a lower end of the first bank portion-side side surface in the second direction is longer than a distance between an upper end and a lower end of a third bank portion-side side surface, which is a side surface of the first groove portion on the third bank portion side, in the second direction. The first electrode is in contact with the semiconductor layer of the first conductivity type in a bottom portion of the first groove portion, and stretches along the first bank portion-side side surface to a top surface of the first bank portion.

In another implementation, in the optical semiconductor device, the third bank portion-side surface is a roughly vertical surface or has a stepped shape including a terrace portion.

In another implementation, the optical semiconductor device according further includes a second groove portion between the second bank portion and the optical function portion.

In another implementation, in the optical semiconductor device, a height from a bottom surface of the first groove portion to a top surface of the terrace portion is equal to or less than half a height from the bottom surface of the first groove portion to the top surface of the first bank portion.

In another implementation, in the optical semiconductor device, a height from a bottom surface of the first groove portion to a top surface of the terrace portion is 20% or more and 40% or less of a height from the bottom surface of the first groove portion to the top surface of the first bank portion.

In another implementation, in the optical semiconductor device, a width of the terrace portion of the first bank portion-side side surface in the second direction is equal to or more than half a height from a bottom surface of the first groove portion to a top surface of the terrace portion, and equal to or less than twice the height.

In another implementation, in the optical semiconductor device, a distance in the second direction from an intersection point between the third bank portion-side side surface and a top surface of the third bank portion to an intersection point between the third bank portion-side surface and a bottom surface of the first groove portion is 1/10 or less of a width of the terrace portion of the first bank portion-side side surface.

In another implementation, in the optical semiconductor, a height from the terrace portion of the first bank portion-side side surface to the top surface of the first bank portion is the same as a height from a bottom surface of the second groove portion to a top surface of the second bank portion.

In another implementation, in the optical semiconductor device, the second electrode stretches from above the optical function portion along an inside of the second groove portion to a top surface of the second bank portion.

In another implementation, the optical semiconductor device further includes a contact layer of the first conductivity type between the semiconductor layer of the first conductivity type and the optical function layer, and the terrace portion of the first bank portion-side side surface is formed in the contact layer of the first conductivity type.

In another implementation, in the optical semiconductor device, the semiconductor layer of the first conductivity type is a semiconductor substrate of the first conductivity type.

In another implementation, the optical semiconductor device further includes: a substrate of the first conductivity type; an etch stop layer of the first conductivity type placed on the substrate; and a contact layer of the first conductivity type which is placed on the etch stop layer, and is formed from a material different from a material of the etch stop layer, and the semiconductor layer of the first conductivity type is the substrate of the first conductivity type.

In another implementation, the optical semiconductor device further includes: a substrate of the first conductivity type; an etch stop layer of the first conductivity type placed on the substrate; and a contact layer of the first conductivity type which is placed on the etch stop layer, and is formed from a material different from a material of the etch stop layer, and the semiconductor layer of the first conductivity type is the etch stop layer.

In another implementation, the optical semiconductor device further includes: a substrate; a high concentration contact layer of the first conductivity type placed on the substrate; an etch stop layer of the first conductivity type placed on the high concentration contact layer; and a contact layer of the first conductivity type which is placed on the etch stop layer, and is lower in impurity concentration than the high concentration contact layer, and the semiconductor layer of the first conductivity type is the high concentration contact layer.

In another implementation, in the optical semiconductor device, the terrace portion of the first bank portion-side side surface includes a first terrace portion and a second terrace portion different from the first terrace portion in height.

In another implementation, in the optical semiconductor device, the first electrode includes a first contact electrode and a first lead-out electrode in contact with the first contact electrode, the first contact electrode is in contact with the semiconductor layer of the first conductivity type in a bottom portion of the first groove portion, and the first lead-out electrode stretches from above the first contact electrode along the terrace portion of the first bank portion-side surface to the top surface of the first bank portion.

In another implementation, in the optical semiconductor device, the second electrode includes a second contact electrode and a second lead-out electrode in contact with the second contact electrode, the second contact electrode is in contact with the semiconductor layer of the second conductivity type in an upper portion of the optical function portion, and the second lead-out electrode stretches from above the second contact electrode along an inside of the second groove portion to a top surface of the second bank portion.

In another implementation, in the optical semiconductor device, the optical function layer included in the optical function portion is sandwiched by a block layer of a semiconductor, and the semiconductor layer of the second conductivity type is placed on the optical function layer and the block layer.

In another implementation, in the optical semiconductor device, the optical function layer is placed in the optical function portion, the first bank portion, the second bank portion, and the third bank portion.

In another implementation, in the optical semiconductor device, the terrace portion of the first bank portion-side side surface is wider in the second direction than the terrace portion of the third bank portion-side side surface.

### BRIEF DESCRIPTION OF THE DRAWINGS

FIG. 1 is a bird's eye view of an optical semiconductor device according to a first example implementation of the present invention.

FIG. 2 is a schematic sectional view taken along the line II-II of the optical semiconductor device illustrated in FIG. 1.

FIG. 3A is a diagram for illustrating a method of manufacturing the optical semiconductor device.

FIG. 3B is a diagram for illustrating the method of manufacturing the optical semiconductor device.

FIG. 3C is a diagram for illustrating the method of manufacturing the optical semiconductor device.

FIG. 3D is a diagram for illustrating the method of manufacturing the optical semiconductor device.

FIG. 3E is a diagram for illustrating the method of manufacturing the optical semiconductor device.

FIG. 3F is a diagram for illustrating the method of manufacturing the optical semiconductor device.

FIG. 4 is a schematic sectional view taken along the line II-II of an optical semiconductor device according to Modification Example 1 of the first example implementation.

FIG. 5 is a schematic sectional view taken along the line II-II of the optical semiconductor device according to Modification Example 1 of the first example implementation.

FIG. 6 is a schematic sectional view taken along the line II-II of an optical semiconductor device according to Modification Example 2 of the first example implementation.

FIG. 7 is a schematic sectional view taken along the line II-II of an optical semiconductor device according to Modification Example 3 of the first example implementation.

FIG. 8 is a schematic sectional view of an optical semiconductor device according to a second example implementation of the present invention that corresponds to FIG. 2.

FIG. 9 is a bird's eye view of an optical semiconductor device according to a third example implementation of the present invention.

FIG. 10 is a schematic sectional view taken along the line X-X of the optical semiconductor device illustrated in FIG. 9.

### DETAILED DESCRIPTION

The following detailed description of example implementations refers to the accompanying drawings. Throughout the drawings, like reference numerals may be used to represent members having like functions, and description thereof may be omitted for the sake of simplicity. The drawings referred to in the following are only for illustrating implementations by way of examples, and are not necessarily drawn to scale.

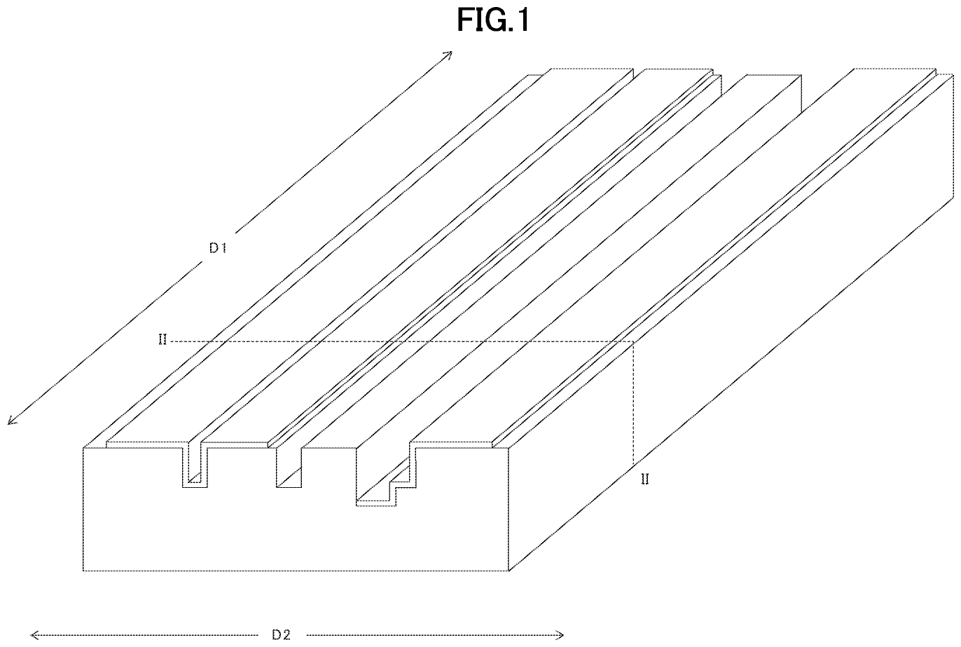

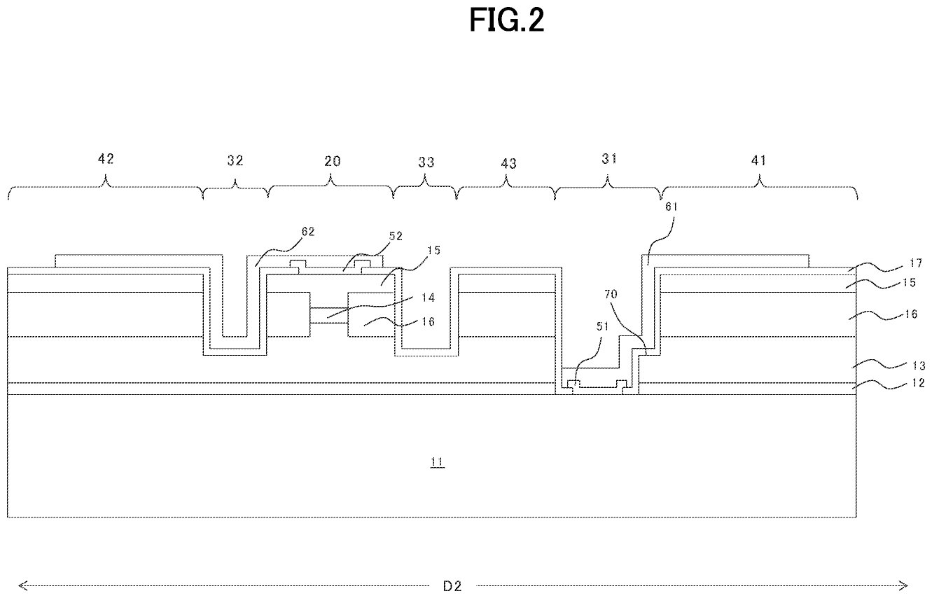

FIG. 1 is a bird's eye view of an optical semiconductor device according to a first example implementation of the present invention. FIG. 2 is a schematic sectional view taken along the line II-II of FIG. 1. A case in which the optical semiconductor device is an optical amplifier is described in the following example implementation. However, the optical semiconductor device is not limited thereto and may be any one of a semiconductor laser, an optical modulator, or a photo diode, among other examples.

The optical semiconductor device may include a substrate 11. The substrate 11 may be a single-crystal substrate, and may be a conductive or semi-insulating semiconductor substrate, or another crystal substrate. Here, the substrate 11 may be a semiconductor substrate of a first conductivity type, for example, an n-type InP substrate. A semiconductor multilayer described herein may be placed on the substrate 11.

As illustrated in FIG. 2, the semiconductor multilayer may have a concavo-convex structure. A direction in which an optical function layer 14 (described herein) stretches may be a first direction D1, a direction perpendicular to the first direction D1 in plan view may be a second direction D2. The optical semiconductor device may include a semiconductor layer of the first conductivity type, the optical function layer 14 placed above the semiconductor layer of the first conductivity type, a semiconductor layer of a second conductivity type placed above the optical function layer 14, a first electrode electrically connected to the semiconductor layer of the first conductivity type, and a second electrode electrically connected to the semiconductor layer of the second conductivity type. The optical semiconductor device also may include a first bank portion 41 in which a part of the first electrode may be placed, a first groove portion 31 adjacent to the first bank portion, a second bank portion 42 in which a part of the second electrode may be placed, a third bank portion 43, a third groove portion 33 adjacent to the third bank portion, and an optical function portion 20 including the optical function layer 14. The optical semiconductor device may include or omit a second groove portion 32. Specifically, the optical semiconductor device may include the optical function portion 20 including the optical function layer 14, and may have the second groove portion 32 on one side of the optical function portion 20 and the third groove portion 33 on another side of the optical function portion 20. The optical semiconductor device may have the second bank portion 42 next to the second groove portion 32. The optical semiconductor device may have the third bank portion 43 next to the third groove portion 33. The optical semiconductor device may have the first groove portion 31 next to the third bank portion 43. The optical semiconductor device may have the first bank portion 41 next to the first groove portion 31. In short, in the second direction that is, in plan view, perpendicular to the first direction along which the optical function portion 20 stretches, the first bank portion 41, the first groove portion 31, the third bank portion 43, the third groove portion 33, the optical function portion 20, the second groove portion 32, and the second bank portion 42 may be placed in the stated order. Details of the respective structures are described herein.

An etch stop layer 12 of the first conductivity type may be formed on the substrate 11. A material of the etch stop layer 12 differs from a material of a first contact layer 13 described herein and, here, may be InGaAs having the first conductivity type. The etch stop layer 12 is not limited thereto and may be formed from other materials. For example, the material of the etch stop layer 12 may be InGaAsP. The first contact layer 13 of the first conductivity type may be formed on the etch stop layer 12. The first contact layer 13 may be, for example, an n-type InP layer. The optical function layer 14 may be formed on a part of the first contact layer 13. The optical function layer 14 may be a place in which a current (carriers) and light interact with each other. For example, the optical function layer 14 may be a multiple quantum well layer or a bulk layer formed from a semiconductor. Here, the optical function layer 14 may include a multiple quantum well layer of InGaAsP. The optical function portion 20 may include another layer above and/or below the optical function layer 14. For example, the optical function portion 20 may include an optical confinement layer. A second contact layer 15 of the second conductivity type may be formed on the optical function layer 14. The second contact layer 15 may be, for example, a p-type InP layer. A block layer 16 may be formed on each side of the optical function layer 14. The block layer 16 may be also formed in a part of an area between the first contact layer 13 and the second contact layer 15. The block layer 16 may be placed in order to concentrate a voltage applied (a current injected) to the second contact layer 15 onto the optical function layer 14. The block layer 16 may be configured from a semiconductor layer of the first conductivity type and a semiconductor layer of the second conductivity type that may be grown on top of each other, or semi-insulating semiconductor layers grown on top of each other, or a combination thereof. The “semiconductor multilayer” refers to the semiconductor layers located between the etch stop layer 12 and the second contact layer 15 (including the etch stop layer 12 and the second contact layer 15). Another semiconductor layer may be placed on the second contact layer 15 in order to reduce a contact resistance of contact with a second contact electrode 52 described herein. In that case, another semiconductor layer for reducing the contact resistance may be included in the semiconductor multilayer as well. Although the first conductivity type may be the “n” type and the second conductivity type may be the “p” type here, which conductivity type may be the “n” type or the “p” type may be reversed.

The optical function portion 20 may include the first contact layer 13, the optical function layer 14, the second contact layer 15, and the block layer 16. The substrate 11 (e.g., the semiconductor layer of the first conductivity type) may be present on a bottom surface of the first groove portion 31, details of which are described herein. The first contact layer 13 may be present below the second groove portion 32 and the third groove portion 33. The first bank portion 41, the second bank portion 42, and the third bank portion 43 each include the first contact layer 13, the block layer 16, and the second contact layer 15.

The optical semiconductor device may include an insulating film 17. The insulating film 17 may be placed on the semiconductor multilayer except a part of an area above the optical function portion 20 and a part of a bottom portion of the first groove portion 31. The insulating film 17 may be, for example, a silicon oxide film.

The optical semiconductor device may include a first contact electrode 51 and a first lead-out electrode 61. The first contact electrode 51 may be electrically and physically connected to the semiconductor layer of the first conductivity type. The first lead-out electrode 61 may be in contact with the first contact electrode 51 in the bottom portion of the first groove portion 31, and may stretch along a side surface of the first groove portion 31 on the first bank portion 41 side, to a top surface of the first bank portion 41. The side surface of the first groove portion 31 on the first bank portion 41 side may be hereinafter referred to as a “first bank portion-side side surface.” Further, a side surface of the first groove portion 31 on the third bank portion 43 side may be hereinafter referred to as a “third bank portion-side side surface.” Specifically, the first contact electrode 51 may be placed in the bottom portion of the first groove portion 31. The first lead-out electrode 61 may be connected to the first contact electrode 51. The first lead-out electrode 61 may stretch along the first bank portion-side side surface to the top surface of the first bank portion 41. In FIG. 2, a part of the insulating film 17 may be placed between a part of the first contact electrode 51 and the substrate 11. However, the insulating film 17 may be positioned so as not to be placed in this part. Here, the semiconductor layer of the first conductivity type may be the substrate 11. The first contact electrode 51 and the first lead-out electrode 61 may be, for example, metal layers, and may have a multilayer structure including layers of Ti, Pt, Au, and/or the like. The first contact electrode 51 and the first lead-out electrode 61 may have the same layer structure or different layer structures. The first contact electrode 51 and the first lead-out electrode 61 here form the first electrode. The first contact electrode 51 may be omitted. In this case, the first lead-out electrode 61 may be connected directly to the substrate 11.

The optical semiconductor device may include a second contact electrode 52 and a second lead-out electrode 62. The second contact electrode 52 may be electrically and physically connected to the semiconductor layer of the second conductivity type in the optical function portion 20. Here, the semiconductor layer of the second conductivity type may be the second contact layer 15. The insulating film 17 may be placed between a part of the second contact electrode 52 and the second contact layer 15. The second lead-out electrode 62 may be connected to the second contact electrode 52. The second lead-out electrode 62 may stretch along an inside of the second groove portion 32 to a top surface of the second bank portion 42. The second contact electrode 52 and the second lead-out electrode 62 may be, for example, metal layers, and may my have a multilayer structure including layers of Ti, Pt, Au, and/or the like. The second contact electrode 52 and the second lead-out electrode 62 may have the same layer structure or different layer structures. The second contact electrode 52 and the second lead-out electrode 62 here form the second electrode. The second contact electrode 52 may be omitted. In this case, the second lead-out electrode 62 may be connected directly to the second contact layer 15.

The optical semiconductor device may be electrically connected to an outside at the first lead-out electrode 61 of the first bank portion 41 and the second lead-out electrode 62 of the second bank portion 42. The electrical connection to the outside may be established via wires or via an electrical connection material such as solder.

A notable feature of the present invention resides in the shape of the first groove portion 31. As illustrated in FIG. 2, the side surface of the first groove portion 31 on the third bank portion 43 side (the third bank portion-side side surface) may have a smooth shape without a level difference, and the side surface of the first groove portion 31 on the first bank portion 41 side (the first bank portion-side side surface) may have a stepped shape with two levels. In other words, the third bank portion-side side surface may have a smooth shape without a level difference that may be at an angle of 90 (±10) degrees with respect to the substrate 11, and a terrace portion 70 may be formed on the first bank portion-side side surface. The first lead-out electrode 61 may stretch from the bottom portion of the first groove portion 31 along a shape of the terrace portion 70 to the top surface of the first bank portion 41. A side surface from the substrate 11 to the terrace portion 70 and a side surface from the terrace portion 70 to the top surface of the first bank portion 41 may include no terrace portion and may be gently rising surfaces. An angle formed by each of the rising surfaces and the substrate 11 may be 90 (±10) degrees. Places in which the terrace portion 70 connects to other surfaces that are the rising surfaces may have a right angle shape in FIG. 2, but actually may have a shape with a rounded corner. The present disclosure may be characterized by the side surface of the first groove portion 31 on the first bank portion 41 side including at least one terrace portion 70 whereas the side surface of the first groove portion 31 on the third bank portion 43 side may have no terrace shape. A height from the bottom surface of the first groove portion 31 to a top surface of the terrace portion 70 may be lower than a height from the top surface of the terrace portion 70 to the top surface of the first bank portion 41. When viewed from a direction in which the layers of the semiconductor multilayer are grown on top of one another, the top surface of the terrace portion 70 may be preferred to be positioned lower than a midpoint between the bottom surface of the first groove portion 31 and the top surface of the first bank portion 41. The terrace portion 70 may be preferred to be placed at a position of 40% or less. In the following, a position of X % means a position at which the top surface of the terrace portion 70 is located when a position of a top surface of the substrate 11 is 0% and a position of the top surface of the first bank portion 41 is 100%. For example, the position of 40% means a state in which the height from the substrate 11 to the top surface of the terrace portion 70 is 40% and the height from the top surface of the terrace portion 70 to the top surface of the first bank portion 41 is 60%. The terrace portion 70 may be also preferred to be placed at a position of 20% or more. When the terrace portion 70 is too close to the bottom surface of the first groove portion 31, an effect of improving connectivity of the electrode described herein may weaken.

The third bank portion-side side surface may include a very small level difference formed when the groove is formed, instead of being the roughly vertical surface (smooth surface) that has absolutely no terrace portion 70 as in FIG. 2. For example, when the semiconductor multilayer composed of a plurality of materials is etched, differences in etching rate among the materials give the third bank portion-side side surface a slightly undulating shape in some cases. However, the magnitude of the undulation in the second direction D2 may be 1/10 or less of a width of the terrace portion 70 of the first bank portion-side side surface, and it can accordingly be said that the third bank portion-side side surface is a surface having substantially no terrace portion 70. In the present invention, the third bank portion-side side surface being a roughly vertical surface is defined as a distance from an intersection point between the third bank portion-side side surface and a top surface of the third bank portion 43 to an intersection point between the third bank portion-side side surface and the bottom surface of the first groove portion 31 in the second direction being 1/10 or less of the width of the terrace portion 70 of the first bank portion-side side surface.

In order to establish electrical connection between the first lead-out electrode 61 placed on the top surface of the first bank portion 41 and the substrate 11, the first lead-out electrode 61 may be required to be continuous from the bottom portion of the first groove portion 31 to the top surface of the first bank portion 41. If the first bank portion-side side surface is a roughly vertical surface without the terrace portion 70, the first lead-out electrode 61 may become thin on this side surface. In this case, resistance of the first lead-out electrode 61 increases between the bottom portion of the first groove portion 31 and the top surface of the first bank portion 41. At worst, the first lead-out electrode 61 may break between the bottom portion of the first groove portion 31 and the top surface of the first bank portion 41. In the first example implementation, however, the level difference per step included in the first bank portion-side side surface is small owing to the provision of the terrace portion 70, and the possibility of occurrence of the problem described above is accordingly reduced. Further, compared to the case of giving a side surface of a groove a tapered shape, the distance between the bottom portion of the first groove portion 31 and the top surface of the first bank portion 41 in the second direction D2 may be shortened. As a result, two advantageous effects are provided, which are prevention of a drop in connectivity of the first lead-out electrode 61 and prevention of an increase in device size, both of which are obtained in a compatible manner. In addition, the connectivity of the first lead-out electrode 61 may be secured more stably by placing the terrace portion 70 below the position of 50%. When the first lead-out electrode 61 is formed, deposition of the first lead-out electrode 61 on the side surface of the first groove portion 31 becomes increasingly difficult as the distance to the bottom portion of the first groove portion 31 closes. However, this is avoidable by placing the terrace portion 70 at a position closer to the bottom surface of the first groove portion 31 than to the top surface of the first bank portion 41. That the third bank portion-side side surface may have a roughly vertical surface shape without a stepped shape is also important. For example, when both side surfaces of a groove portion are given a tapered shape, enlargement in device size has significant adverse effects. In the first example implementation, however, enlargement in device size is prevented by adopting a configuration that places no terrace portion 70 on the third bank portion-side side surface. The width of the terrace portion 70 in the second direction D2 may be preferred to be equal to or more than half a distance (height) from the substrate 11 to the terrace portion 70 and equal to or less than twice the distance (height). A case in which the width of the terrace portion 70 in the second direction D2 is too narrow may be substantially the same as the case in which the first bank portion-side side surface is a roughly vertical surface, and a mode in which the width of the terrace portion 70 in the second direction D2 is too narrow may be accordingly undesirable. Further, in a case in which the width of the terrace portion 70 in the second direction D2 is too wide, the effect of preventing enlargement in device size diminishes.

An effect of keeping the first contact electrode 51 or the first lead-out electrode 61 from connecting to the second lead-out electrode 62 may be obtained by providing the third groove portion 33 and the third bank portion 43. For example, there may be a possibility that the second lead-out electrode 62 placed above the optical function portion 20 reaches a side surface of the third groove portion 33 on the optical function portion 20 side and a bottom portion of the third groove portion 33 due to production tolerance or other factors. For example, in a case of a structure without the third bank portion 43, there is often a fear of short circuit when the first contact electrode 51 or the first lead-out electrode 61 accidentally connects to the second lead-out electrode 62 stretching from the optical function portion 20. However, the second lead-out electrode 62 can be kept from reaching the first groove portion 31 by providing the third groove portion 33 and the third bank portion 43 as in the first example implementation. The provision of the third groove portion 33 and the third bank portion 43 may have an effect of preventing the first lead-out electrode 61 and the second lead-out electrode 62 from electrically connecting to each other particularly when the optical semiconductor device is mounted by junction-down mounting. The “junction-down mounting” means mounting the optical semiconductor device so that a top surface (a surface on which the first lead-out electrode 61 and the second lead-out electrode 62 are formed) faces a mounting substrate. The first lead-out electrode 61 and the second lead-out electrode 62 may be connected by solder to two electrodes formed on the mounting substrate. Solder melted on a metal surface may have wettability that causes the solder to spread along the metal surface. For example, when solder in contact with the second lead-out electrode 62 spreads to the first lead-out electrode 61 side (the first groove portion 31 side), there may be a fear of short circuit between the first lead-out electrode 61 and the second lead-out electrode 62. However, owing to the presence of the third groove portion 33, the solder spreading from the second lead-out electrode 62 stays in the third groove portion 33, and is further prevented from overflowing to the first groove portion 31 side by the third bank portion 43.

In the first example implementation, the height from the top surface of the terrace portion 70 to the top surface of the first bank portion 41 may be roughly the same as a depth of the second groove portion 32 (a height from a bottom surface of the second groove portion 32 to a top surface of the second bank portion 42). The wording “roughly the same” here means “the same in a range of layers formed by the same manufacturing process.” The second lead-out electrode 62 stretches from above the optical function portion 20 along a side surface and the bottom surface of the second groove portion 32 to the top surface of the second bank portion 42. A configuration in which the second groove portion 32 is too deep is undesirable because connectivity of the second lead-out electrode 62 drops. The second groove portion 32 accordingly may have a depth that secures connection of the second lead-out electrode 62. The first lead-out electrode 61 may be securely connected between the terrace portion 70 and the top surface of the first bank portion 41 by positioning the top surface of the terrace portion 70 flush with the bottom surface of the second groove portion 32. Further, the height from the bottom surface of the first groove portion 31 to the top surface of the terrace portion 70 may be lower than the height from the top surface of the terrace portion 70 to the top surface of the first bank portion 41. The first lead-out electrode 61 accordingly may have excellent connectivity also in a region from the bottom portion of the first groove portion 31 to the terrace portion 70. The third groove portion 33 may have any depth, but it may be desired to have the same depth as the depth of the second groove portion 32 because the third groove portion 33 may be desired to be formed by the same process as the process of the second groove portion 32.

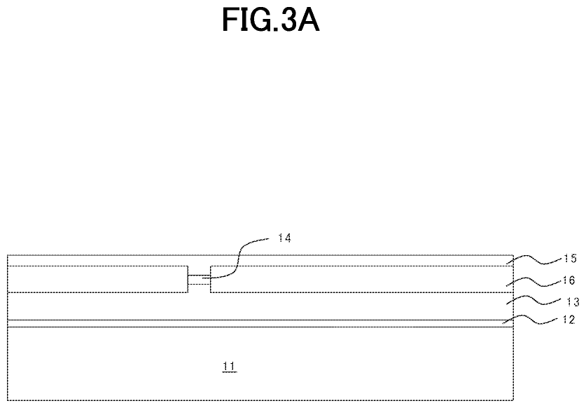

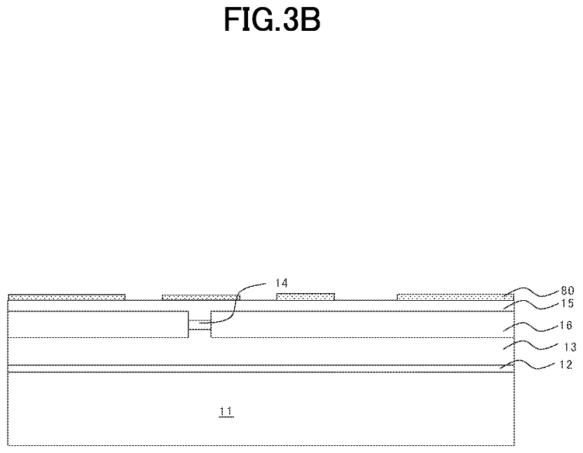

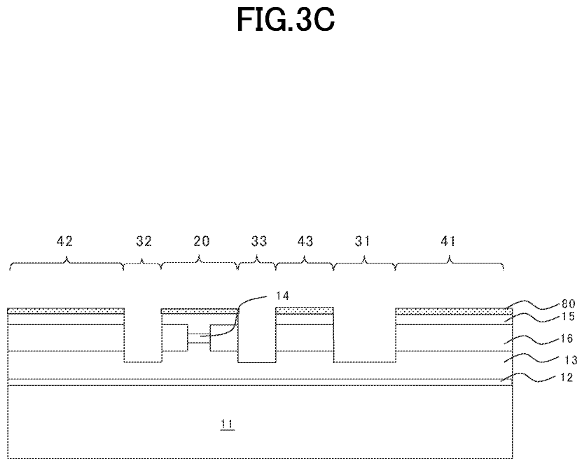

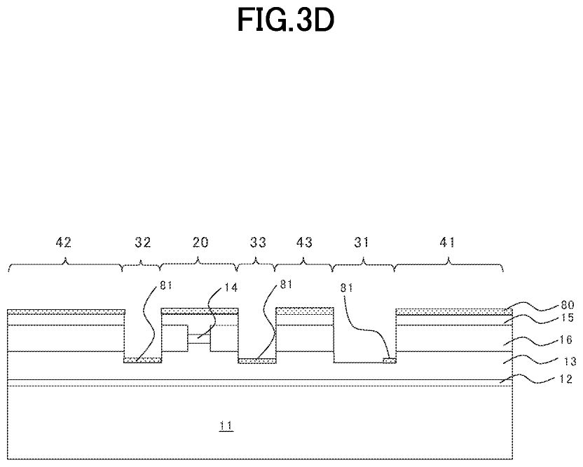

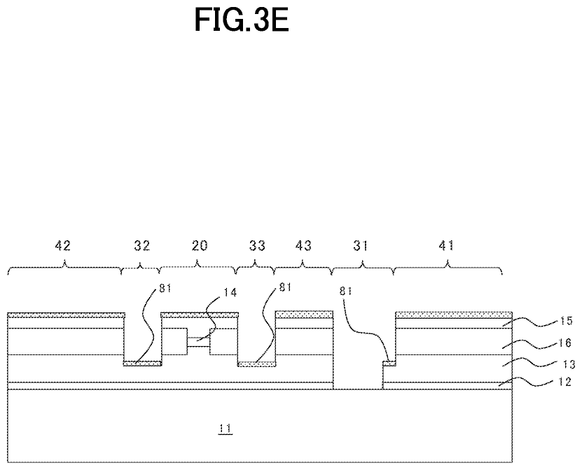

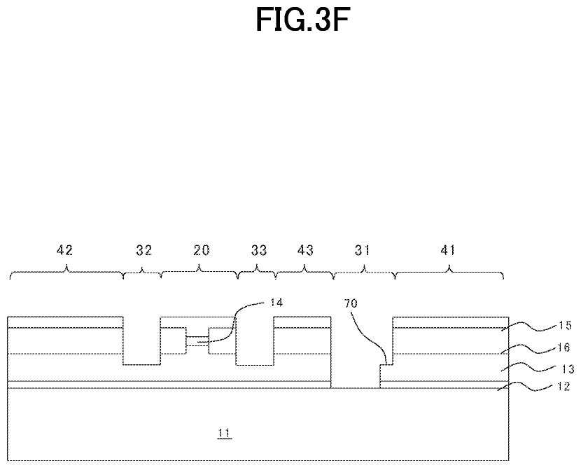

There may be no limitation on a method of manufacturing the first groove portion 31, the second groove portion 32, and the third groove portion 33. An example is given in FIG. 3A to FIG. 3F, which are diagrams for illustrating a method of manufacturing the optical semiconductor device. First, the semiconductor multilayer may be formed by epitaxial growth on the substrate 11 (FIG. 3A). After the epitaxial growth of the semiconductor multilayer, a groove forming mask 80 for forming grooves may be placed in regions to become the optical function portion 20, the first bank portion 41, the second bank portion 42, and the third bank portion 43 (FIG. 3B). Etching may be performed after the groove forming mask 80 is placed, to thereby form a part of the first groove portion 31 as well as the second groove portion 32 and the third groove portion 33 (FIG. 3C). The etching lasts until the second groove portion 32 is formed. At this point of time, the second groove portion 32 and the third groove portion 33 may be formed. Further, the bottom surface of the first groove portion 31 at this point of time may be flush with a level at which the top surface of the terrace portion 70 may be positioned when the terrace portion 70 is completed. Next, a terrace forming mask 81 for forming the terrace portion 70 may be placed (FIG. 3D). The terrace forming mask 81 may cover all but a region in which the bottom surface of the first groove portion 31 is ultimately formed. Etching may then be performed until the etch stop layer 12 is exposed. In this etching, the first contact layer 13 may be etched. At this time, selective etching may be executable for the etching of the first contact layer 13 because the first contact layer 13 and the etch stop layer 12 may be formed from different materials. As a result, a smooth top surface of the etch stop layer 12 may be exposed in the bottom portion of the first groove portion 31. Further, etching may be performed to etch the etch stop layer 12, with use of chemical different from one used in the etching described above. The etch stop layer 12 and the substrate 11 may be formed from different materials and, accordingly, a smooth surface of the substrate 11 may be exposed, with the substrate 11 functioning as an etch stop layer for the etch stop layer 12 (FIG. 3E). All masks may be then removed. The first groove portion 31 may thus be formed (FIG. 3F). The insulating film 17 may then be formed. A desired region of the insulating film 17 may be removed, to thereby form a through-hole. Next, the first contact electrode 51 may be formed in the bottom portion of the first groove portion 31. Connectivity between the first contact electrode 51 and the substrate 11 at this time may be excellent because the bottom surface of the first groove portion 31 may be smooth. The second contact electrode 52 may be formed by the same process as a process used to form the first contact electrode 51, or may be formed by a different process. Lastly, the first lead-out electrode 61 and the second lead-out electrode 62 may be formed to complete the optical semiconductor device. The first lead-out electrode 61 and the second lead-out electrode 62 may be formed by the same manufacturing process or different manufacturing processes.

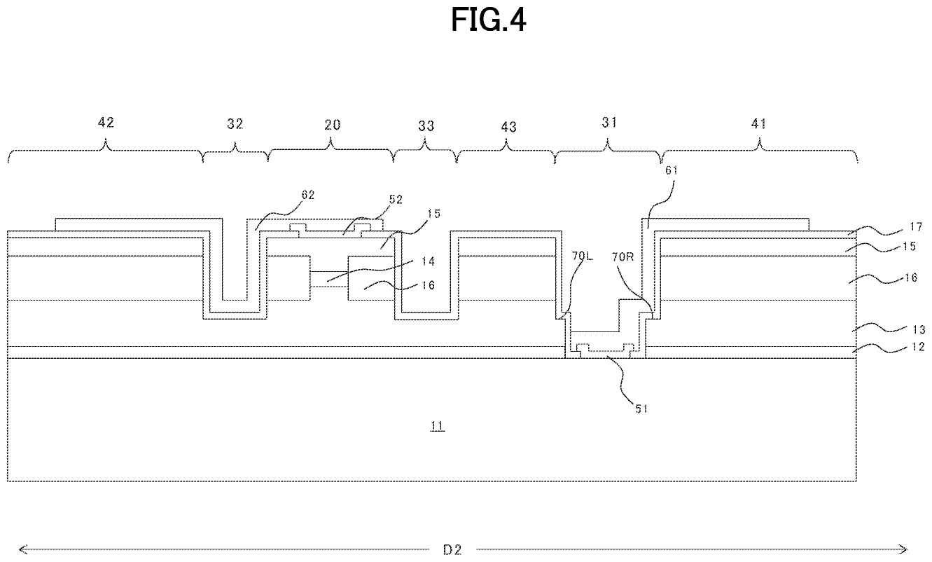

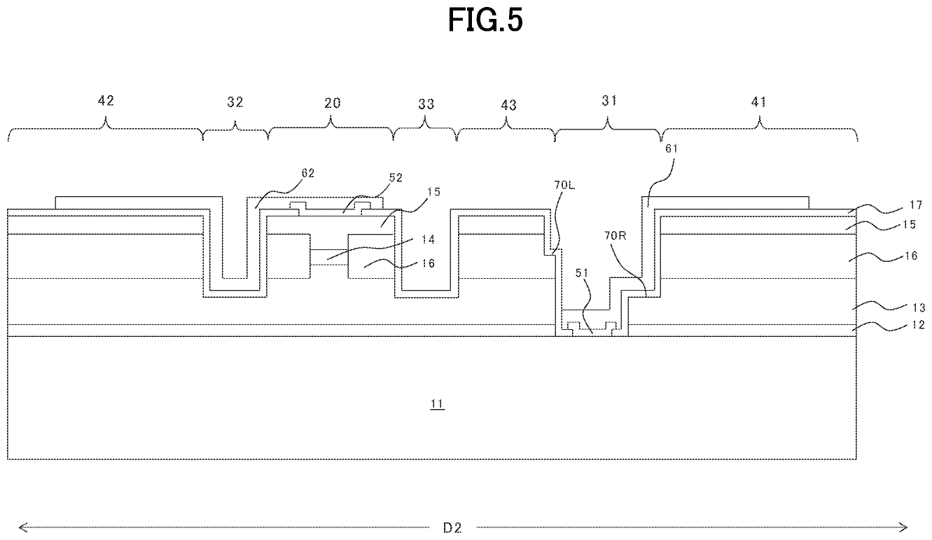

FIG. 4 and FIG. 5 are each a schematic sectional view taken along the line II-II of an optical semiconductor device according to Modification Example 1 of the first example implementation. A difference from the first example implementation is that the third bank portion-side side surface of the first groove portion 31 has a stepped shape including a terrace portion 70L. According to the manufacturing method described above, in the step of placing the terrace forming mask 81 of FIG. 3D, the terrace forming mask 81 may be required to be positioned to fit around a part of the already formed first groove portion 31. However, the terrace forming mask 81 may be misaligned in the second direction D2 in some cases. For example, when the terrace forming mask 81 is misaligned rightward in FIG. 3D, the terrace portion 70L may be formed on the third bank portion-side side surface as illustrated in FIG. 4. In addition, a terrace portion 70R of the first bank portion-side side surface of the first groove portion 31 may have a width in the second direction D2 that is smaller than that in the first example implementation by an amount equivalent to a distance of the misalignment of the terrace forming mask 81. When the terrace forming mask 81 is misaligned rightward in FIG. 3D as illustrated in FIG. 4, the terrace portion 70R of the first bank portion-side side surface and the terrace portion 70L of the third bank portion-side side surface may be at the same height when viewed from the substrate 11. Further, in a case in which the terrace forming mask 81 is misaligned leftward in FIG. 3D, the terrace portion 70L may be formed on the third bank portion-side side surface as illustrated in FIG. 5. In addition, the terrace portion 70R of the first bank portion-side side surface may have a width in the second direction D2 that may be larger than that in the first example implementation by an amount equivalent to the distance of the misalignment of the terrace forming mask 81. In the case in which the terrace forming mask 81 is misaligned leftward in FIG. 3D as illustrated in FIG. 5, the terrace portion 70L of the third bank portion-side side surface may be formed at a position higher than the terrace portion 70R of the first bank portion-side side surface when viewed from the substrate 11. As in Modification Example 1, even when the terrace forming mask 81 is misaligned, the two effects of preventing the connectivity of the first lead-out electrode 61 from dropping and preventing enlargement in device size may be obtained in a compatible manner. Note that the terrace portion 70R of the first bank portion-side side surface is wider in the second direction D2 than the terrace portion 70L of the third bank portion-side side surface.

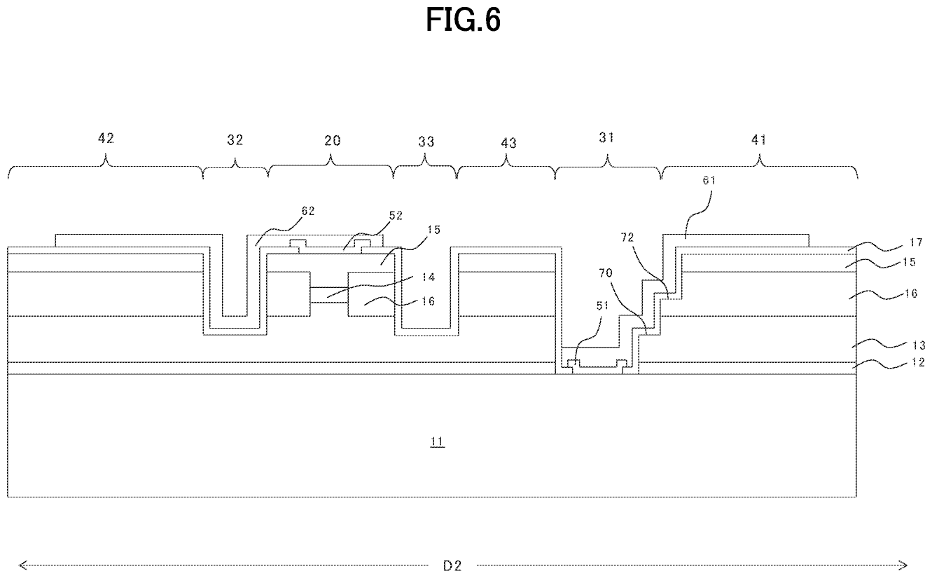

FIG. 6 is a schematic sectional view taken along the line II-II of an optical semiconductor device according to Modification Example 2 of the first example implementation. A difference from the first example implementation is that the first bank portion-side side surface of the first groove portion 31 includes two terrace portions. In Modification Example 2, the first bank portion-side side surface of the first groove portion 31 may include a second terrace portion 72 in addition to the terrace portion 70. In the first example implementation, the height from the terrace portion 70 to the top surface of the first bank portion 41 may be higher than the height from the bottom surface of the first groove portion 31 to the top surface of the terrace portion 70. The connectivity of the first lead-out electrode 61 may accordingly drop. This may be preventable by placing the second terrace portion 72 between the terrace portion 70 and the top surface of the first bank portion 41. The connectivity of the first lead-out electrode 61 may be stabilized by increasing the number of terrace portions in the manner described above. On the other hand, an increase in number of terrace portions invites enlargement in device size. A preferred number of terrace portions to be formed on the first bank portion-side side surface may be accordingly one or two.

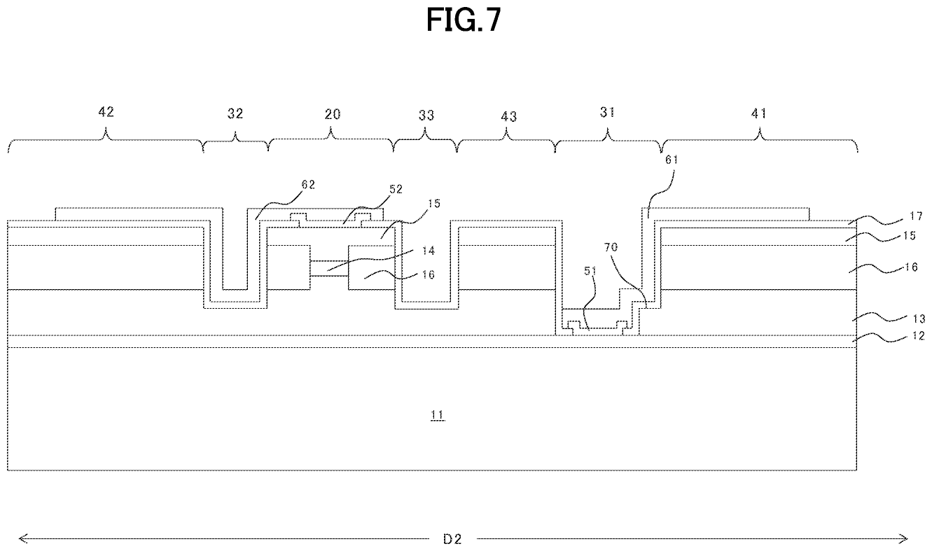

FIG. 7 is a schematic sectional view taken along the line II-II of an optical semiconductor device according to Modification Example 3 of the first example implementation. A difference from the first example implementation is that the bottom surface of the first groove portion 31 is the top surface of the etch stop layer 12. Here, the semiconductor layer of the first conductivity type may be the etch stop layer 12. As described in the first example implementation, the bottom surface of the first groove portion 31 (the top surface of the etch stop layer 12) may be a smooth surface even when the process of forming the first groove portion 31 (the etching step of FIG. 3F) is ended with the bottom surface of the first groove portion 31 serving as the top surface of the etch stop layer 12. There may be accordingly no problem in connectivity between the first contact electrode 51 and the etch stop layer 12, which is the semiconductor layer of the first conductivity type. According to Modification Example 3, the depth of the first groove portion 31 may be decreased, albeit slightly, compared to the first example implementation, with the result that the stability of connection of the first lead-out electrode 61 is improved.

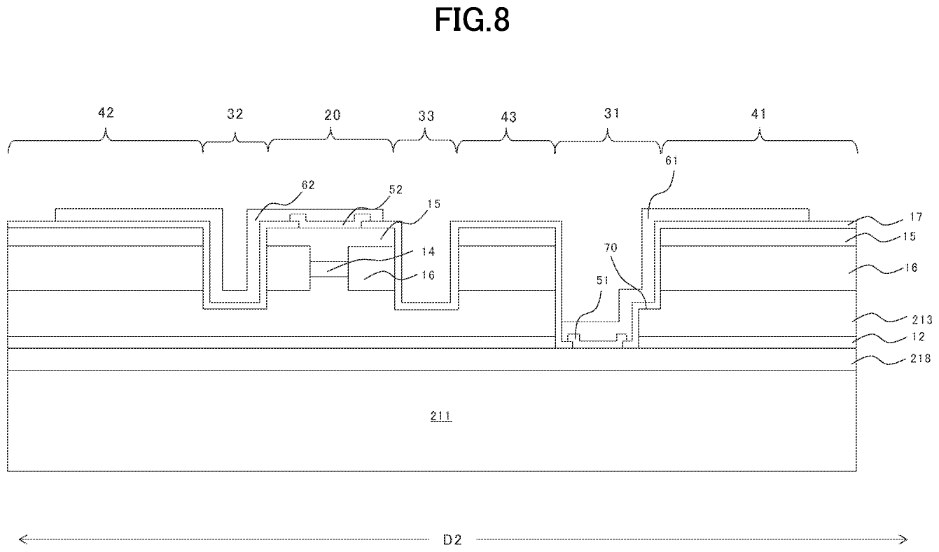

FIG. 8 is a schematic sectional view of an optical semiconductor device according to a second example implementation of the present invention. FIG. 8 corresponds to the schematic sectional view taken along the line II-II of the first example implementation. The optical semiconductor device of the second example implementation may include an insulating substrate 211. A semiconductor multilayer may be formed on a top surface of the insulating substrate 211, and a concavo-convex structure similar to the concavo-convex structure of the first example implementation may be placed therein.

A high concentration contact layer 218 of the first conductivity type may be formed on the substrate 211. The semiconductor layer of the first conductivity type here may be the high concentration contact layer 218. The etch stop layer 12 of the first conductivity type may be formed on the high concentration contact layer 218. A first contact layer 213 of the first conductivity type may be formed on the etch stop layer 12. Semiconductor layers above the first contact layer 213 may be the same as the semiconductor layers in the first example implementation. In the second example implementation, layers from the high concentration contact layer 218 to the second contact layer 15 may be the semiconductor multilayer.

The high concentration contact layer 218 and the first contact layer 213 may be of the same conductivity type and formed from the same material as well. Here, the high concentration contact layer 218 and the first contact layer 213 may be n-type InP layers. However, the high concentration contact layer 218 may be higher in impurity concentration than the first contact layer 213. A material of the etch stop layer 12 differs from the material of the high concentration contact layer 218 and the first contact layer 213. The etch stop layer 12 may be of the first conductivity type. The bottom surface of the first groove portion 31 may be a top surface of the high concentration contact layer 218.

A semiconductor layer decreases in resistance but increases in light absorption amount as the impurity concentration rises. Light transmitted through the optical semiconductor device spreads upward and downward, and leftward and rightward, with the optical function layer 14 as the center. In a case in which the first contact layer 213 close to the optical function layer 14 may have a high impurity concentration, the light absorption amount increases and the increase may result in insufficient optical characteristics of the optical semiconductor device. In a case in which the first contact layer 213 may be given a low impurity concentration for the purpose of reducing the light absorption amount, resistance of the first contact layer 213 increases. For example, in a case of employing a configuration in which the first contact electrode 51 connects directly to the first contact layer 13 having a low concentration in the first example implementation, it means that a semiconductor layer high in resistance may be interposed among layers from the first contact electrode 51 to the optical function layer 14, and the configuration consequently leads to deterioration of characteristics of the optical semiconductor device. A length in the second direction D2 from the first contact electrode 51 to a region below the optical function layer 14 is, for example, several ten micrometers (μm). Meanwhile, in the second example implementation, the first contact electrode 51 may be connected to the high concentration contact layer 218 low in resistance. The first contact layer 213 close to the optical function layer 14 may be low in impurity concentration and may be accordingly small in light absorption amount. In this case, regions from the first contact electrode 51 to the region below the optical function layer 14 may be electrically connected by the high concentration contact layer 218 low in resistance. The etch stop layer 12 and the first contact layer 213 may be interposed in a region stretching from below the optical function layer 14 to the high concentration contact layer 218. However, a thickness of the etch stop layer 12 and the first contact layer 213 may be on the order of several μm, and may be sufficiently smaller than the distance between the optical function layer 14 and the first contact electrode 51 in the second direction D2 (several ten μm). Accordingly, high resistance of the first contact layer 213 poses no problem. According to the second example implementation, the light absorption amount may be reduced with an increase in resistance of the semiconductor layer kept under control. The structure in which the third bank portion-side side surface may include no tapered shape in the first example implementation may be excellent from this viewpoint of resistance as well. When the side surface on the light function layer side has a tapered shape, the optical function layer and the bottom surface of the first groove portion may be further distanced from each other. The resistance may be accordingly higher even more. In the first example implementation, however, because the third bank portion-side side surface may include no tapered shape, the distance between the optical function layer 14 and the first contact electrode 51 in the second direction D2 may be shorter than that in the case in which the third bank portion-side side surface includes a tapered shape. An adverse effect of an increase in resistance of the first contact layer 213 is accordingly prevented.

The same advantageous effects as the advantageous effects of the first example implementation may be obtained also in the second example implementation. Modification Example 1 to Modification Example 3 of the first example implementation may be applied to the second example implementation as well.

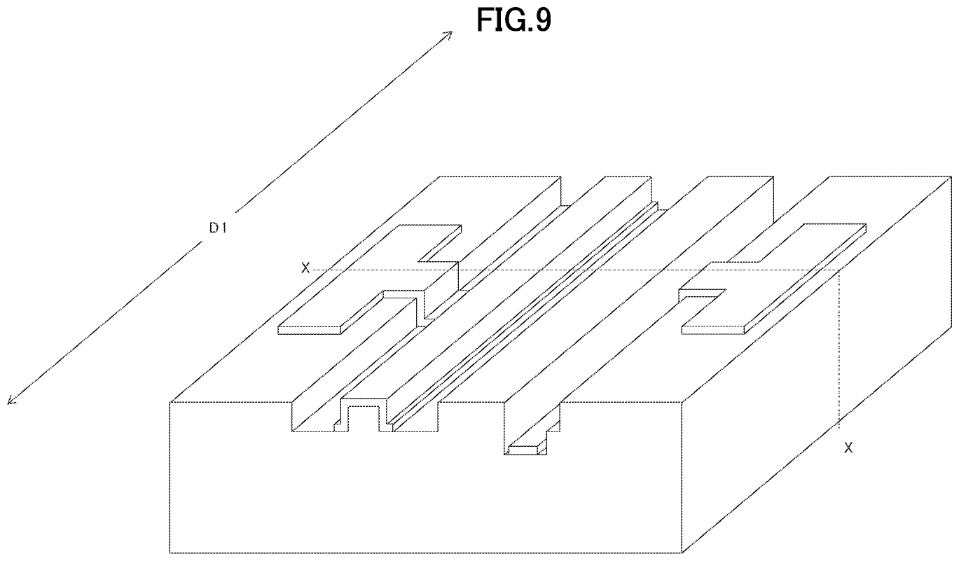

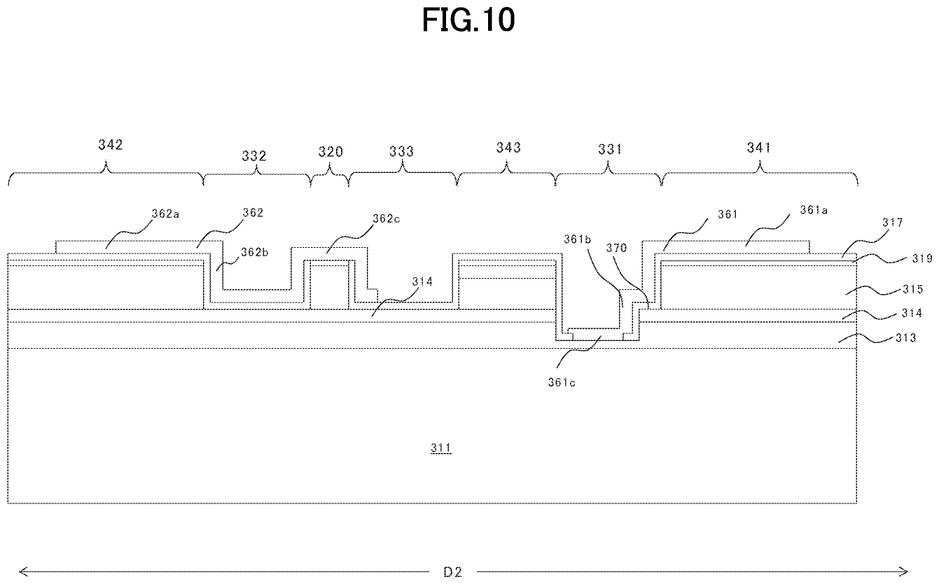

FIG. 9 is a bird's eye view of an optical semiconductor device according to a third example implementation of the present invention. FIG. 10 is a schematic sectional view taken along the line X-X of FIG. 9. The optical semiconductor device illustrated in FIG. 9 and FIG. 10 may be a ridge-type optical semiconductor device, here, a direct modulation semiconductor laser. However, the optical semiconductor device is not limited thereto, and may be any one of an optical amplifier, an optical modulator, and a photo diode.

The optical semiconductor device may include a substrate 311. The substrate 311 may be a single-crystal substrate, and may be a conductive or semi-insulating semiconductor substrate, or another crystal substrate. Here, the substrate 311 may be a semiconductor substrate of a first conductivity type, for example, an n-type InP substrate. A semiconductor multilayer described herein may be placed on the substrate 311.

As illustrated in FIG. 10, the semiconductor multilayer may have a concavo-convex structure. The optical semiconductor device may include, as a region in which a second lead-out electrode 362 described herein and the semiconductor multilayer are in contact with each other, an optical function portion 320 having a mesa structure. The optical semiconductor device may have a second groove portion 332 on one side of the optical function portion 320 and a third groove portion 333 on another side of the optical function portion 320. The optical semiconductor device may have a second bank portion 342 next to the second groove portion 332. The optical semiconductor device may have a third bank portion 343 next to the third groove portion 333. The optical semiconductor device may have a first groove portion 331 next to the third bank portion 343. The optical semiconductor device may have a first bank portion 341 next to the first groove portion 331. Details of the respective structures are described herein.

A first cladding layer 313 of the first conductivity type may be formed on the substrate 311. Here, the first cladding layer 313 may be an n-type InP layer. An optical function layer 314 may be formed on the first cladding layer 313. The optical function layer 314 may be a place in which a current (carriers) and light interact with each other. For example, the optical function layer 314 may be a multiple quantum well layer or a bulk layer formed from a semiconductor. Here, the optical function layer 314 may include a multiple quantum well layer of InGaAsP. The optical function portion 320 may include another layer above and/or below the optical function layer 314. For example, the optical function portion 320 may include an optical confinement layer or a diffraction grating layer. A second cladding layer 315 of the second conductivity type may be formed on the optical function layer 314. The second cladding layer 315 is, for example, a p-type InP layer. A contact layer 319 of the second conductivity type may be formed on the second cladding layer 315. The contact layer 319 may be, for example, a p-type InGaAs layer. The “semiconductor multilayer” refers to the semiconductor layers located between the first cladding layer 313 and the contact layer 319 (including the first cladding layer 313 and the contact layer 319).

The optical function portion 320, the first bank portion 341, the second bank portion 342, and the third bank portion 343 may include the same semiconductor multilayer. A bottom surface of the first groove portion 331 may be positioned in the first cladding layer 313, but may be positioned in the substrate 311 when the substrate 311 is a conductive substrate. Bottom surfaces of the second groove portion 332 and the third groove portion 333 may be a top surface of the optical function layer 314. The “top surface of the optical function layer 314” does not always mean a top surface of the multiple quantum well layer, and means, for example, a top surface of the optical confinement layer in a case of a configuration in which the optical confinement layer is placed above the multiple quantum well layer.

The optical semiconductor device may include an insulating film 317. The insulating film 317 may be placed on a top surface of the semiconductor multilayer except a top surface of the optical function portion 320 and a part of a bottom surface of the first groove portion 331. The insulating film 317 is, for example, a silicon oxide film.

The optical semiconductor device may include a first lead-out electrode 361 connected electrically and physically to a semiconductor layer of the first conductivity type. Here, the semiconductor layer of the first conductivity type may be the first cladding layer 313. In FIG. 10, a part of the insulating film 317 may be placed between a part of the first lead-out electrode 361 and the first cladding layer 313, but a configuration in which the part of the insulating film 317 is not placed there may be employed. The first lead-out electrode 361 stretches along a first bank portion-side side surface to a top surface of the first bank portion 341. The first lead-out electrode 361 may be configured from three regions, which may be a region (pad region 361a) placed on the top surface of the first bank portion 341, a region (connection region 361b) placed on a side surface of the first groove portion 331 on the first bank portion 341 side, and a region (contact region 361c) placed on the first cladding layer 313 (a bottom portion of the first groove portion 331). A length in the first direction D1 may be longest in the contact region 361c and shortest in the connection region 361b. The contact region 361c may be placed so as to spread wide in the first direction D1 in order to reduce connection resistance in connection between the semiconductor layer (first cladding layer 313) and the first lead-out electrode 361. Meanwhile, in order to accommodate for high-speed driving, the pad region 361a and the connection region 361b may be preferred to be small in parasitic capacitance. In order to reduce parasitic capacitance, lengths of the pad region 361a and the connection region 361b in the first direction D1 may be preferred to be short. The size of the pad region 361a may be required to be large to a degree for connection to the outside. However, the connection region 361b may be preferred to have a small size as long as the small size does not give high resistance to the electrode, and may be the smallest among the three regions. The first lead-out electrode 361 is, for example, a metal layer, and may have a multilayer structure including layers of Ti, Pt, Au, and/or the like. Further, the pad region 361a, the connection region 361b, and the contact region 361c may be configured unitarily. Here, the first lead-out electrode 361 may be the first electrode.

The optical semiconductor device may include the second lead-out electrode 362 connected electrically and physically to a semiconductor layer of the second conductivity type in the optical function portion 320. The semiconductor layer of the second conductivity type here may be the contact layer 319. The second lead-out electrode 362 stretches along an inside of the second groove portion 332 to a top surface of the second bank portion 342. The second lead-out electrode 362 may be configured from three regions, which may be a region (pad region 362a) placed on the top surface of the second bank portion 342, a region (connection region 362b) placed on the inside of the second groove portion 332, and a region (contact region 362c) placed on an upper portion of the optical function portion 320. The contact region 362c may include not only the top surface of the mesa structure but also a side surface of the mesa structure and a part of a surface beside the side surface. Similarly to the first lead-out electrode 361, a length in the first direction D1 may be shortest (narrowest) in the connection region 362b. The second lead-out electrode 362 is, for example, a metal layer, and may have a multilayer structure including layers of Ti, Pt, Au, and/or the like. Further, the pad region 362a, the connection region 362b, and the contact region 362c may be configured unitarily. Here, the second lead-out electrode 362 may be the second electrode.

The optical semiconductor device may be electrically connected to the outside at the pad region 361a on the first bank portion 341 and the pad region 362a on the second bank portion 342. The electrical connection to the outside may be established via wires or via an electrical connection material such as solder.

The side surface of the first groove portion 331 on the first bank portion 341 side may include a terrace portion 370. Meanwhile, a side surface of the first groove portion 331 on the third bank portion 343 side may be a roughly vertical surface. Here, a top surface of the terrace portion 370 may be the top surface of the optical function layer 314. In other words, a height from the top surface of the first bank portion 341 to the top surface of the terrace portion 370 may be the same as a depth of the second groove portion 332. Other features may be the same as those in the first example implementation.

The same advantageous effects as the advantageous effects of the first example implementation may be obtained also in the third example implementation. Further, Modification Example 1 to Modification Example 3 of the first example implementation may be applied to the third example implementation as well.

The present invention is not limited to the example implementations described above, and various modifications may be made thereto. For example, the configuration described in the example implementations may be replaced by substantially a same configuration, a configuration having a same action and effect, and/or a configuration which may achieve a same object.

The present invention accomplishes, in the optical semiconductor device in which the first electrode and the second electrode for applying a voltage to the optical function portion are placed on the same surface, improvement in connectivity of the electrodes and prevention of enlargement of the device size in a compatible manner. This may be accomplished in the example implementations of the present invention by placing the terrace portion on one side surface of the first groove portion for connecting the first electrode to the semiconductor layer of the first conductivity type below the optical function layer. A side surface of the first groove portion on the opposite side (a side surface on the optical function portion side) may include a roughly vertical surface or a terrace portion. The terrace portion may be placed at a position below a midpoint of the height of the first groove portion, such as a position of 20% or more and 40% or less. The width of the terrace portion may be half the height from the bottom surface of the first groove portion to the terrace portion or more, and twice the height or less. The optical function portion-side side surface of the first groove portion may be a roughly vertical surface. The roughly vertical surface may include a small level difference or undulation, but a width in a lateral direction from an upper end of the side surface to a lower end of the side surface may be 1/10 or less of the width of the terrace portion. In the case in which a terrace portion is included on the optical function portion side of the first groove portion as well, this terrace portion may be narrower in width than the terrace portion on the side surface on the opposite side. The first electrode may be in contact with the semiconductor layer of the first conductivity type on the bottom surface of the first groove portion. The semiconductor layer of the first conductivity type may be any one of the substrate, the contact layer of the first conductivity type, the etch stop layer formed from a material different from a material of the contact layer of the first conductivity type, and the high concentration contact layer containing impurities in a concentration higher than an impurity concentration of the contact layer of the first conductivity type. The present invention may include the second groove portion on one side of the optical function portion and the third groove portion on another side of the optical function portion. The depth of the second groove portion may be the same as a depth to the terrace portion in the first groove portion. The second electrode may stretch from the top surface of the optical function portion along the inside of the second groove portion.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical semiconductor device, comprising:
a semiconductor layer of a first conductivity type;
an optical function layer placed above the semiconductor layer of the first conductivity type;
a semiconductor layer of a second conductivity type placed above the optical function layer;
a first electrode electrically connected to the semiconductor layer of the first conductivity type;
a second electrode electrically connected to the semiconductor layer of the second conductivity type;
a first bank portion in which a part of the first electrode is placed;
a first groove portion adjacent to the first bank portion;
a second bank portion in which a part of the second electrode is placed;
a third bank portion;
a third groove portion adjacent to the third bank portion; and
an optical function portion including the optical function layer,
wherein, in a second direction that is, in plan view, perpendicular to a first direction along which the optical function portion stretches, the first bank portion, the first groove portion, the third bank portion, the third groove portion, the optical function portion, and the second bank portion are placed in the stated order,
wherein the second electrode is in contact with the semiconductor layer of the second conductivity type in the optical function portion,
wherein a first bank portion-side side surface, which is a side surface of the first groove portion on the first bank portion side, has a stepped shape including a terrace portion,
wherein a distance between an upper end and a lower end of the first bank portion-side side surface in the second direction is longer than a distance between an upper end and a lower end of a third bank portion-side side surface, which is a side surface of the first groove portion on the third bank portion side, in the second direction, and
wherein the first electrode is in contact with the semiconductor layer of the first conductivity type in a bottom portion of the first groove portion, and stretches along the first bank portion-side side surface to a top surface of the first bank portion.

2. The optical semiconductor device according to claim 1, wherein the third bank portion-side surface is a roughly vertical surface or has a stepped shape including a terrace portion.

3. The optical semiconductor device according to claim 1, further comprising a second groove portion between the second bank portion and the optical function portion.

4. The optical semiconductor device according to claim 1, wherein a height from a bottom surface of the first groove portion to a top surface of the terrace portion is equal to or less than half a height from the bottom surface of the first groove portion to the top surface of the first bank portion.

5. The optical semiconductor device according to claim 1, wherein a height from a bottom surface of the first groove portion to a top surface of the terrace portion is 20% or more and 40% or less of a height from the bottom surface of the first groove portion to the top surface of the first bank portion.

6. The optical semiconductor device according to claim 1, wherein a width of the terrace portion of the first bank portion-side side surface in the second direction is equal to or more than half a height from a bottom surface of the first groove portion to a top surface of the terrace portion, and equal to or less than twice the height.

7. The optical semiconductor device according to claim 1, wherein a distance in the second direction from an intersection point between the third bank portion-side side surface and a top surface of the third bank portion to an intersection point between the third bank portion-side side surface and a bottom surface of the first groove portion is 1/10 or less of a width of the terrace portion of the first bank portion-side side surface.

8. The optical semiconductor device according to claim 3, wherein a height from the terrace portion of the first bank portion-side side surface to the top surface of the first bank portion is the same as a height from a bottom surface of the second groove portion to a top surface of the second bank portion.

9. The optical semiconductor device according to claim 3, wherein the second electrode stretches from above the optical function portion along an inside of the second groove portion to a top surface of the second bank portion.

10. The optical semiconductor device according to claim 1, further comprising a contact layer of the first conductivity type between the semiconductor layer of the first conductivity type and the optical function layer,
wherein the terrace portion of the first bank portion-side side surface is formed in the contact layer of the first conductivity type.

11. The optical semiconductor device according to claim 1, wherein the semiconductor layer of the first conductivity type is a semiconductor substrate of the first conductivity type.

12. The optical semiconductor device according to claim 1, further comprising:
a substrate of the first conductivity type;
an etch stop layer of the first conductivity type placed on the substrate; and
a contact layer of the first conductivity type which is placed on the etch stop layer, and is formed from a material different from a material of the etch stop layer,
wherein the semiconductor layer of the first conductivity type is the substrate of the first conductivity type.

13. The optical semiconductor device according to claim 1, further comprising:
a substrate of the first conductivity type;
an etch stop layer of the first conductivity type placed on the substrate; and
a contact layer of the first conductivity type which is placed on the etch stop layer, and is formed from a material different from a material of the etch stop layer,
wherein the semiconductor layer of the first conductivity type is the etch stop layer.

14. The optical semiconductor device according to claim 1, further comprising:
a substrate;
a high concentration contact layer of the first conductivity type placed on the substrate;
an etch stop layer of the first conductivity type placed on the high concentration contact layer; and
a contact layer of the first conductivity type which is placed on the etch stop layer, and is lower in impurity concentration than the high concentration contact layer,
wherein the semiconductor layer of the first conductivity type is the high concentration contact layer.

15. The optical semiconductor device according to claim 1, wherein the terrace portion of the first bank portion-side side surface includes a first terrace portion and a second terrace portion different from the first terrace portion in height.

16. The optical semiconductor device according to claim 1,
wherein the first electrode includes a first contact electrode and a first lead-out electrode in contact with the first contact electrode,
wherein the first contact electrode is in contact with the semiconductor layer of the first conductivity type in a bottom portion of the first groove portion, and
wherein the first lead-out electrode stretches from above the first contact electrode along the terrace portion of the first bank portion-side side surface to the top surface of the first bank portion.

17. The optical semiconductor device according to claim 3,
wherein the second electrode includes a second contact electrode and a second lead-out electrode in contact with the second contact electrode,
wherein the second contact electrode is in contact with the semiconductor layer of the second conductivity type in an upper portion of the optical function portion, and
wherein the second lead-out electrode stretches from above the second contact electrode along an inside of the second groove portion to a top surface of the second bank portion.

18. The optical semiconductor device according to claim 1,
wherein the optical function layer included in the optical function portion is sandwiched by a block layer of a semiconductor, and
wherein the semiconductor layer of the second conductivity type is placed on the optical function layer and the block layer.

19. The optical semiconductor device according to claim 1, wherein the optical function layer is placed in the optical function portion, the first bank portion, the second bank portion, and the third bank portion.

20. The optical semiconductor device according to claim 2, wherein the terrace portion of the first bank portion-side side surface is wider in the second direction than the terrace portion of the third bank portion-side side surface.
